(19) United States
(12) Patent Application Publication
(10) Pub. No.: US 2020/0373109 A1
(43) Pub. Date: Nov. 26, 2020

(54) Fuse assembly and method of making

(71) Applicant: Rosemount Aerospace, Inc., Burnsville, MN (US)

(72) Inventors: David P. Potasek, Lakeville, MN (US); Ben Ping-Tao Fok, Rosemount, MN (US); Roger Alan Backman, Eagan, MN (US)

(21) Appl. No.: 16/418,332

(22) Filed: May 21, 2019

(51) Int. Cl. H01H 37/32; H01C 1/16; H01H 37/04; H01H 37/64; H01H 11/00

(52) U.S. Cl. CPC H01H 37/32; H01C 1/16; H01H 11/00; H01H 37/64; H01H 37/04

(57) ABSTRACT

Disclosed is a thin-film micro-fuse assembly having: a substrate; an insulating layer disposed on the substrate, the insulating layer comprising silicon dioxide; a conductor disposed on the insulating layer, the conductor forming: an inlet terminal, an outlet terminal and a fuse element between the inlet terminal and the outlet terminal, the inlet terminal and the outlet terminal widthwise converging toward the fuse element, and the fuse element having a first thickness and a first width that is between 1 and 5 times the first thickness.

### BACKGROUND

The embodiments relate to a fuse and more specifically to a thin-film micro-fuse assembly.

Thin film micro-fuses assemblies (fuse assemblies) can be used as state programming switches. In the ‘ON’ state such assemblies provide a low resistance path for current to flow. When subjected to a high enough current, self-heating occurs such that a fuse element, which is a local area in the fuse assembly, is melted and retreats creating an open or “OFF” state.

### SUMMARY

Disclosed is a thin-film micro-fuse assembly comprising: a substrate; an insulating layer disposed on the substrate, the insulating layer comprising silicon dioxide; a conductor disposed on the insulating layer, the conductor forming: an inlet terminal, an outlet terminal and a fuse element between the inlet terminal and the outlet terminal, the inlet terminal and the outlet terminal widthwise converging toward the fuse element, and the fuse element having a first thickness and a first width that is between 1 and 5 times the first thickness.

In addition to one or more above identified features or as an alternate, the fuse element transitions to the inlet terminal and the outlet terminal with rounded fillets.

In addition to one or more above identified features or as an alternate, opposing ends of the fuse element define a first length that is between 1 and 3 times the first width.

In addition to one or more above identified features or as an alternate, a length between opposing ends of the inlet terminal and the outlet terminal is 2 times the first length.

In addition to one or more above identified features or as an alternate, the inlet terminal and the outlet terminal have a same maximum width that is 10 times the first width.

In addition to one or more above identified features or as an alternate, the conductor has a low melting temperature.

In addition to one or more above identified features or as an alternate, the conductor has a melting temperature of less than 700 degrees Celsius.

In addition to one or more above identified features or as an alternate, the conductor has a melting temperature of less than 660 degrees Celsius.

In addition to one or more above identified features or as an alternate, the conductor comprises aluminum.

In addition to one or more above identified features or as an alternate, the insulating layer has an R value between 0.1e-6 m\hat{ }2 (° C./W) and 1.0e-6 m\hat{ }2 (° C./W).

In addition to one or more above identified features or as an alternate, the insulating layer has an R value of at least 0.28e-6 m\hat{ }2 (° C./W).

In addition to one or more above identified features or as an alternate, the thickness of the insulating layer is between 0.14 μm and 1.4 μm.

In addition to one or more above identified features or as an alternate, the thickness of the insulating layer is at least 0.4 μm.

In addition to one or more above identified features or as an alternate, the insulating layer has a thermal conductivity (Tc) of between 1 W/(mK) and 10 W/(mK).

In addition to one or more above identified features or as an alternate, the insulating layer has a Tc of between 1.3 W/(mK) and 1.5 W/(mK).

In addition to one or more above identified features or as an alternate, the substrate comprises a semiconductor.

Further disclosed is a method of forming a thin-film micro-fuse assembly, comprising: providing a substrate; depositing an insulating layer on the substrate, the insulating layer comprising silicon dioxide; depositing a conductor on the insulating layer so that the conductor forms an inlet terminal, an outlet terminal and a fuse element between the inlet terminal and the outlet terminal, the inlet terminal and the outlet terminal widthwise converging toward the fuse element, and the fuse element having a first thickness and a first width that is between 1 and 5 times the first thickness.

Further disclosed is a series resistor network comprising: a plurality of loops arranged in series between a first resistor node and a second resistor node; each of the plurality of loops including, in parallel, one of a plurality of resistors and one of a plurality of the assemblies having one or more of the features disclosed herein; and a plurality of program nodes respectively connected between the plurality of loops.

A parallel resistor network comprising: a plurality of branches arranged in parallel between a first resistor node and a second resistor node; and each of the plurality of branches including, in series, one of a plurality of resistors, one of a plurality of program nodes, and one of a plurality of the assemblies having one or more of the features disclosed herein.

In addition to one or more above identified features or as an alternate, the network includes another branch arranged in parallel to the plurality of branches, the other branch consisting of another resistor.

### BRIEF DESCRIPTION OF THE DRAWINGS

The present disclosure is illustrated by way of example and not limited in the accompanying figures in which like reference numerals indicate similar fuse elements.

FIG. 1 illustrates a film micro-fuse assembly (fuse assembly) according to an embodiment;

FIG. 2 illustrates a fuse assembly after a fuse element of the fuse assembly has melted;

FIG. 3 is a method of forming a fuse assembly;

FIG. 4 is a series resistor network having a plurality of the disclosed assemblies; and

FIG. 5 is a parallel resistor network having a plurality of the disclosed assemblies.

### DETAILED DESCRIPTION

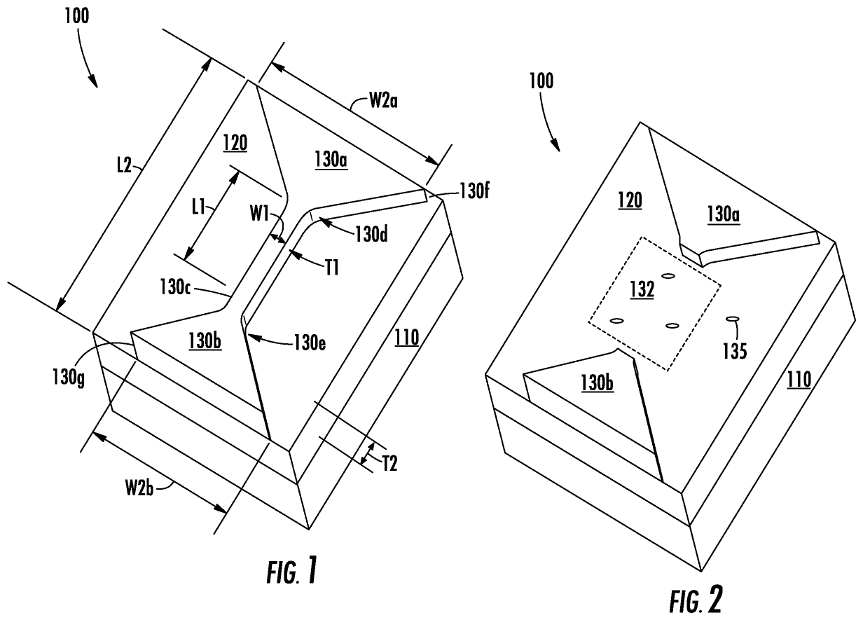

Turning now to FIGS. 1 and 2, disclosed is a thin film micro-fuse assembly (“fuse assembly” or “assembly”) 100 in the closed (on) or open (off) states, respectively. Such a fuse assembly 100 may be suitable as a program switch.

The fuse assembly 100 includes a substrate 110. The substrate 110 may be formed of typical semiconductor. The fuse assembly 100 includes an insulating layer 120, which may be a dielectric, disposed on the substrate 110. A conductor generally referred to as 130 is disposed on the insulating layer 120. The conductor 130 may form an inlet terminal 130a, an outlet terminal 130b and a fuse element 130c therebetween. The fuse terminals 130a, 130b may widthwise converge toward the fuse element 130c in a configuration that may be referred to as an hourglass shape. The fuse terminals 130a, 130b may serve as contacts for integrating the fuse assembly 100 in a circuit.

When the fuse assembly 100 is used as a program switch in electrical and electronic circuits, the program state of the fuse assembly 100 is changed by sending relatively high current through the fuse terminals 130a, 130b to melt the fuse element 130c, thereby blowing the fuse assembly 100. This creates a conductive void 132 between the fuse terminals 130a, 130b, thereby providing an open circuit within the fuse assembly 100. The void 132 should be large enough such that electro-migration affects cannot ‘heal’, that is, conduct electricity between the fuse terminals 130a, 130b despite melting of the fuse element 130d. At the same time, design of the fuse assembly 100 should provide for a compact structure with a thin film conductor 130 and a thin film insulating layer 120.

In view of the requirements of the fuse assembly 100, the conductor 130 may be selected that has a low melting temperature and is highly conductive, to thereby enable, melting the fuse element 130c without significantly increasing current. A target melting temperature, for example, may be under seven hundred (700) degrees Celsius. Thus, according to an embodiment, the conductor 130 is aluminum because it is highly conductive and has a melting temperature of less than approximately sixty (660) degrees Celsius.

Further, the insulating layer 120, while thin, should also provide sufficient insulation to prevent, or limit based on specific requirements, heat and electricity from traveling from the conductor 130 to the substrate 110. A target thickness for example may be between 0.14 μm and 1.4 μm and a target thermal insulating value (R) of the insulating layer 120 may be between 0.1e-6 m\hat{ }2 (° C./W) and 1.0e-6 m\hat{ }2 (° C./W). An insulating value R of a material is a product of its thermal conductivity (Tc) and thickness. Thus, to obtain the target thickness, a suitable material has a Tc of between one (1.0) W/(mK) and ten (10.0) W/(mK). Thus, according to an embodiment, the insulating layer 120 is silicone dioxide because it has a Tc of between 1.3 W/(mK) and 1.5 W/(mK). At a thickness of around 0.4 μm, which is within the target thickness range for the insulating layer 120, silicon dioxide provides an R value of 0.28e-6 m\hat{ }2 (° C./W), which is within the target R value range for the insulating layer 120.

In addition, inherent surface adhesion energy, interfacial tension and wettability characteristics of silicon dioxide enable the aluminum conductor 130 to stick to the insulating layer 120 prior to melting, to form beads 135 upon melting, and remain as beads 135 during subsequent hardening (FIG. 2). The formation of stable beads 135 minimizes a possibility of the fuse assembly 100 healing after being blown, thereby preventing current from passing between the fuse terminals 130a, 130b.

Regarding geometry of the fuse assembly 100, the fuse element 130c has a first thickness T1 and a first width W1 that is between one (1) and five (5) times the first thickness T1. This geometric configuration prevents hot spots from creating an uneven melting of the fuse element 130c and an incomplete separation between the fuse terminals 130a, 130b. In addition, the fuse element 130c transitions to the fuse terminals 130a, 130b, at opposing ends of the fuse element 130d, 130e, with rounded fillets. This transition reduces the occurrence of hot spots at the opposing ends of the fuse element 130d, 130e during the useful life of the fuse assembly 100.

The fuse element 130c has a first length L1 that is between one (1) and three (3) times the first width W1. With this geometric configuration, the void 132 that is obtained upon melting the fuse element 130c provides sufficient separation between the fuse terminals 130a, 130b. In addition, with this geometric configuration, the fuse element 130c is sufficiently short enough to achieve a localized melt of the fuse element 130c while also maintaining a compact size for the fuse assembly 100.

Opposing ends 130f, 130g of the respective fuse terminals 130a, 130b are separated by a second length L2. At the respective opposing ends 130f, 130g, the inlet terminal 130a has a first maximum width W2a and the outlet terminal 130b has a second maximum width W2b. In one embodiment the hourglass shape of the fuse assembly 100 is substantially symmetric so that the fuse terminals 130a, 130b both have the first maximum width W2a. In one embodiment, the second length L2 is about two (2) times the first length L1, and the first maximum width W2a is about ten (10) times the first width W1. This geometric configuration prevents an excess current concentration from building in the fuse terminals 130a, 130b during the useful life of the fuse assembly 100.

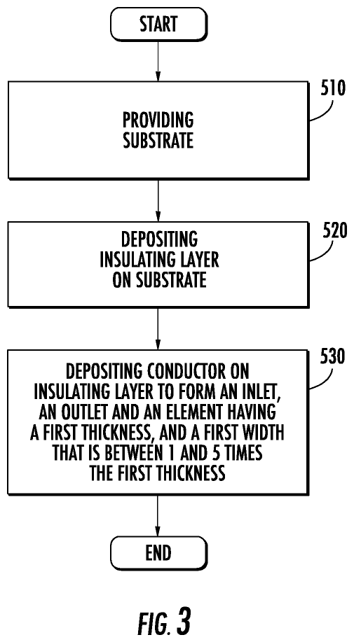

Turning to FIG. 3, a method of forming the fuse assembly 100 is disclosed. The method includes Block 510 providing the substrate 110. The method further includes Block 520 of depositing the insulating layer 120 on the substrate 110. The insulating layer 120, as indicated, comprises silicon dioxide. The method further includes Block 530 depositing the conductor 130 on the insulating layer so that the conductor 130 includes the inlet terminal 130a, the outlet terminal 130b and the fuse element 130c between the inlet terminal 130a and the outlet terminal 130b. As indicated the fuse terminals 130a, 130b widthwise converge toward the fuse element 130c, and the fuse element 130c has a first thickness T1 and a first width W1 that is between one (1) and five (5) times the first thickness T1.

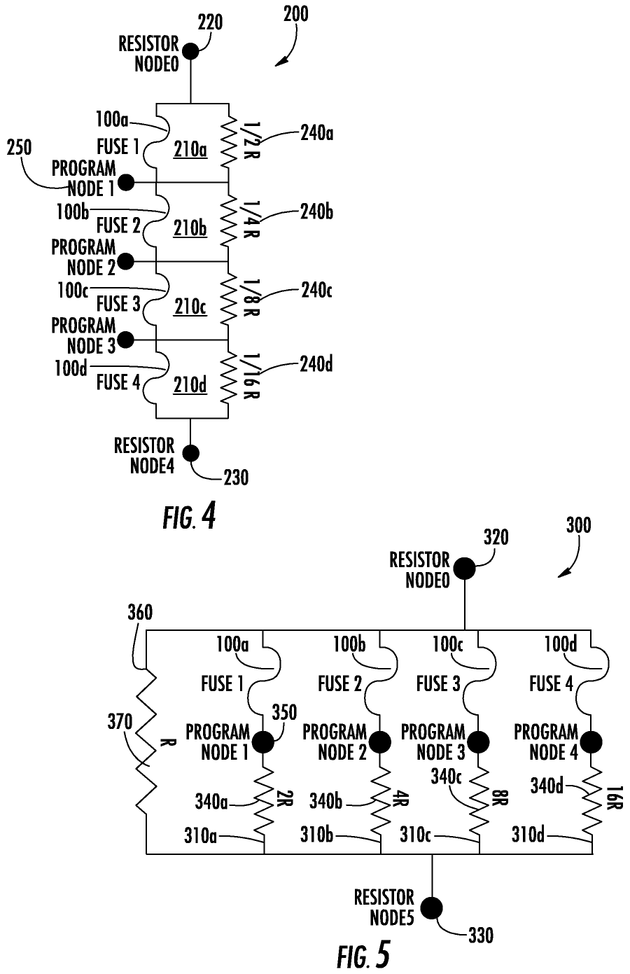

Turning to FIG. 4, further disclosed is a series resistor network (SRN) 200. The SRN 200 includes a plurality of loops generally referred to as 210 arranged in series between a first resistor node 220 and a second resistor node 230. In the SRN 200, each of the plurality of loops 210 includes, in parallel, one of a plurality of resistors generally referred to as 240 and one of a plurality of the fuse assemblies generally referred to as 100, including fuse assemblies 100a-100d. The SRN 200 includes a plurality of program nodes generally referred to as 250 respectively connected between the plurality of loops 210. In the illustrated embodiment there are four loops 210a-210d with a respective four resistors 240a-240d. The four loops 210a-210d are sequentially arranged so that the first loop 210a is proximate the first resistor node 220 and the fourth loop 210d is proximate the second resistor node 230. The resistors 240 in the SRN 200 range in resistivity of between 1/16 R ohms at the first resistor 240a and ½ R ohms at the fourth resistor 240d, where each resistor in the sequence doubles the resistance of the next lower resistor in the sequence. As indicated, in the SRN 200, the fuse assemblies 100 function as switches which are controlled by applying or changing current in the respective program nodes 220. Thus, one or more of the program nodes 220 will selectively receive enough current to blow a respective one or more of the fuse assemblies 100, thereby changing, by a predetermined extent, electrical characteristics in the SRN 200.

Turning to FIG. 5, further disclosed is a parallel resistor network (PRN) 300. The PRN 300 includes a plurality of branches generally referred to as 310 arranged in parallel between a first resistor node 320 and a second resistor node 330. In the PRN 300, each of the plurality of branches 310 includes, in series, one of a plurality of resistors generally referred to as 340, one of a plurality of program nodes generally referred to as 350, and one of a plurality of the fuse assemblies generally referred to as 100, including fuse assemblies 100a-100d. In the illustrated embodiment there are four branches 310a-310d with a respective four resistors 340a-340d. The four branches 310a-310d are sequentially arranged, e.g., from left to right. The resistors 340 in the PRN 300 range in resistivity of between 2R and 16R, where 2R is the resistivity of the first resistor 340a and 16R is the resistivity of the fourth resistor 34de, and where each resistor in the sequence doubles the resistance of the next lower resistor in the sequence. The PRN 300 includes another branch 360 arranged in parallel to the plurality of branches 310, which consists of another resistor 370. The other branch 360 prevent the occurrence of open circuit between the first resistor node 320 and the second resistor node 330 if all of the fuse assemblies 100 were to blow. As with the SRN 200, the fuse assemblies 100 in the PRN 300 function as switches which are controlled by applying or changing current in the respective program nodes 350. Thus, as with the SRN 200, one or more of the program nodes 350 will selectively receive enough current to blow a respective one or more of the fuse assemblies 100, thereby changing, by a predetermined extent, electrical characteristics in the PRN 300

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, assemblies, and/or components, but do not preclude the presence or addition of one or more other features, integers, steps, operations, assembly components, and/or groups thereof.

Those of skill in the art will appreciate that various example embodiments are shown and described herein, each having certain features in the particular embodiments, but the present disclosure is not thus limited. Rather, the present disclosure can be modified to incorporate any number of variations, alterations, substitutions, combinations, sub-combinations, or equivalent arrangements not heretofore described, but which are commensurate with the scope of the present disclosure. Additionally, while various embodiments of the present disclosure have been described, it is to be understood that aspects of the present disclosure may include only some of the described embodiments. Accordingly, the present disclosure is not to be seen as limited by the foregoing description, but is only limited by the scope of the appended claims.

What is claimed is:

1. A fuse assembly comprising:
a substrate;
an insulating layer disposed on the substrate, the insulating layer comprising silicon dioxide;
a conductor disposed on the insulating layer, the conductor comprising:
an inlet terminal;
an outlet terminal; and
a fuse element between the inlet terminal and the outlet terminal, the inlet terminal and the outlet terminal widthwise narrowing toward the fuse element, and the fuse element having a first thickness and a first width, the first width being between 1 and 5 times the first thickness.

2. The assembly of claim 1, wherein a transition between the fuse element and the inlet terminal and the outlet terminal includes rounded fillets.

3. The assembly of claim 1, wherein opposing ends of the fuse element define a first length that is between 1 and 3 times the first width.

4. The assembly of claim 1, wherein a length between opposing ends of the inlet terminal and the outlet terminal is 2 times the first length.

5. The assembly of claim 1, wherein the inlet terminal and the outlet terminal have a same maximum width that is 10 times the first width.

6. The assembly of claim 1, wherein the conductor has a low melting temperature.

7. The assembly of claim 6, wherein the conductor has a melting temperature of less than 700 degrees Celsius.

8. The assembly of claim 7, wherein the conductor has a melting temperature of less than 660 degrees Celsius.

9. The assembly of claim 8, wherein the conductor comprises aluminum.

10. The assembly of claim 1, wherein the insulating layer has an R value between 0.1e-6 m\hat{ }2 (° C./W) and 1.0e-6 m\hat{ }2 (° C./W).

11. The assembly of claim 10, wherein the insulating layer has an R value of at least 0.28e-6 m 2 (° C./W).

12. The assembly of claim 1, wherein the thickness of the insulating layer is between 0.14 μm and 1.4 μm.

13. The assembly of claim 12, wherein the thickness of the insulating layer is at least 0.4 μm.

14. The assembly of claim 1, wherein the insulating layer has a thermal conductivity (Tc) of between 1 W/(mK) and 10 W/(mK).

15. The assembly of claim 14, wherein the insulating layer has a Tc of between 1.3 W/(mK) and 1.5 W/(mK).

16. The assembly of claim 1, wherein the substrate comprises a semiconductor.

17. A method of forming a fuse assembly, comprising:
providing a substrate;
depositing an insulating layer on the substrate, the insulating layer comprising silicon dioxide;
depositing a conductor on the insulating layer so that the conductor forms an inlet terminal, an outlet terminal and a fuse element between the inlet terminal and the outlet terminal, the inlet terminal and the outlet terminal widthwise narrowing toward the fuse element, the fuse element having a first thickness and a first width, the first width being between 1 and 5 times the first thickness.

18. A series resistor network comprising:
a plurality of loops arranged in series between a first resistor node and a second resistor node;
each of the plurality of loops including, in parallel, one of a plurality of resistors and one of a plurality of the assemblies of claim 1; and
a plurality of program nodes respectively connected between the plurality of loops.

19. A parallel resistor network comprising:
a plurality of branches arranged in parallel between a first resistor node and a second resistor node; and
each of the plurality of branches including, in series, one of a plurality of resistors, one of a plurality of program nodes, and one of a plurality of the assemblies of claim 1.

20. The network of claim 19, including another branch arranged in parallel to the plurality of branches, the other branch consisting of another resistor.
